(19) United States
(12) Patent Application Publication
(10) Pub. No.: US 2026/0253834 A1
(43) Pub. Date: Aug. 27, 2026

(54) Charged Particle Beam System

(71) Applicant: Hitachi High-Tech Corporation, Minato-ku, Tokyo (JP)

(72) Inventors: Kohei SUZUKI, Tokyo (JP); Shunsuke MIZUTANI, Tokyo (JP); Yuzuru MIZUHARA, Tokyo (JP)

(21) Appl. No.: 18/853,913

(22) PCT Filed: Apr. 7, 2023
(86) PCT No.: PCT/JP2023/014391

§ 371 Date: Oct. 3, 2024

(30) Foreign Application Priority Data
Apr. 8, 2022 (JP) 2022-064689

(51) Int. Cl. H01J 37/244; H01J 37/147; H01J 37/26; H01J 37/28

(52) U.S. Cl. CPC H01J 37/244; H01J 37/1474; H01J 37/265; H01J 37/28; H01J 2237/2445; H01J 2237/24578

(57) ABSTRACT

The present disclosure proposes a charged particle beam system achieving both an improvement in throughput and measurement accuracy of a semiconductor pattern measurement process. The charged particle beam system includes: a charged particle beam apparatus including a charged particle source configured to emit a charged particle beam, a stage on which a sample is placed, a first deflector configured to deflect the charged particle beam, a second deflector configured to deflect a signal particle emitted from the sample, a detector configured to detect the signal particle, and a position detection device configured to detect a position of the sample or the stage; and a computer system configured to control an operation of the charged particle beam apparatus. The computer system performs output control of the second deflector based on positional information detected by the position detection device. (see FIG. 1).

### TECHNICAL FIELD

The present disclosure relates to a charged particle beam system.

### BACKGROUND ART

As general forms of charged particle beam apparatuses, scanning electron microscopes can be exemplified. In scanning electron microscopes, beams of primary electrons radiated from electron sources are converged and deflected in electromagnetic fields and are scanned 2-dimensionally on samples. In spots on the sample to which the primary electrons are radiated, secondary electrons having information regarding the samples are generated. The secondary electrons are detected by detectors and are converted into electric signals to generate images in synchronization with scanning positions.

When scanning electron microscopes are used, beams of primary electrons can converge into small sizes. Therefore, images with higher resolutions compared to optical microscopes can be obtained. Therefore, scanning electron microscopes are applied to semiconductor measurement apparatuses that measure dimensions of circuit patterns of semiconductor wafers in semiconductor manufacturing processes.

The degree of integration of semiconductor products continues to increase and higher precision is required for circuit patterns. Therefore, semiconductor measurement apparatuses are also required to have enhanced measurement accuracy. In recent years, demands for entire surface inspection of semiconductor wafers have risen, and thus an improvement in throughput is also required in semiconductor measurement apparatuses. Thus, it is strongly required that both high precision and high throughput are achieved for semiconductor measurement apparatuses.

Semiconductor measurement apparatuses have configurations in which semiconductor wafers are loaded on movable stages, so that primary electrons can be radiated to any positions on the semiconductor wafers. Semiconductor measurement apparatuses have configurations in which radiation positions on samples can be changed by deflecting primary electrons with primary electron deflectors. These configurations are used in combination to perform measurement at designated positions on the semiconductor wafers.

For example, PTL 1 discloses a method of shortening a statically determinate time of a stage and achieving an improvement in throughput. In this method, information regarding a stage state is input to a position control unit and a deviation from a radiation target position of primary electrons is calculated. By adjusting an amount of deflection of a primary electron deflector based on the information, it is possible to supplement a temporal variation of a stage position and radiate the primary electrons to the radiation target position.

PTL 2 discloses a method of canceling a change in information incident on a detector by causing a secondary electron deflector to output secondary electrons in accordance with a primary electron deflector output in order to counteract the change in the information caused to be incident due to a deflection action of the primary electron deflector when the primary electrons are deflected by the primary electron deflector.

### CITATION LIST

### Patent Literature

PTL 1: JP4927506B

PTL 2: JP 5948084B

### SUMMARY OF INVENTION

### Technical Problem

As described above, it is required that both high precision and high throughput are achieved for semiconductor measurement apparatuses.

However, when the technique of PTL 1 is applied, an improvement in throughput is expected, but it is difficult to achieve high precision. That is, when dimensions of semiconductor pattern are measured, a deflection action of the primary electron deflector also affects secondary electrons, and thus a trajectory of the secondary electrons incident on the detector is changed. Accordingly, a change in a detection rate of the detector is caused and a detection signal, that is, an image, is changed, which deteriorates measurement accuracy.

On the other hand, according to the technique of PTL 2, in a radiation position movement operation by a normal primary electron deflector, an influence on the secondary electrons by the primary electron deflector can be cancelled by applying an output of the secondary electron deflector in accordance with the primary electron deflector output.

In the technique of PTL 2, however, a high-speed operation cannot be realized when control is performed on the output of the secondary electron deflector based on the output of the primary electron deflector in order to feed information regarding a stage back to the primary electron deflector.

Further, the secondary electron deflector is a deflector that has an action of allowing primary electrons to pass straight and deflecting only secondary electrons. However, the influence on the primary electrons cannot be completely eliminated due to machining tolerance, assembly tolerance, or the like. Therefore, when the output of the secondary electron deflector is changed during 2-dimensional scanning of the primary electrons on a sample, the secondary electron deflector has an influence on the primary electrons and a primary electron radiation position is slightly shifted, which deteriorates measurement accuracy.

The present disclosure has been made in view of the above circumstances and proposes a technique for achieving both an improvement in throughput and measurement accuracy of semiconductor pattern measurement process.

### Solution to Problem

To solve the above problems, according to an aspect of the present disclosure, a charged particle beam system includes: a charged particle beam apparatus including a charged particle source configured to emit a charged particle beam, a stage on which a sample is placed, a first deflector configured to deflect the charged particle beam, a second deflector configured to deflect a signal particle emitted from the sample, a detector configured to detect the signal particle, and a position detection device configured to detect a position of the sample or the stage; and a computer system configured to control an operation of the charged particle beam apparatus. The computer system performs output control of the second deflector based on positional information detected by the position detection device.

Further features of the present disclosure will be apparent from the description of the present specification and the appended drawings. Aspects of the present disclosure are achieved and realized through the elements and various combinations of the elements, in addition to the following detailed descriptions and the forms of the appended claims.

It is required to understand that the technique of the present specification are merely a typical example and is not intended to limit the claims and application examples of the present disclosure in any way.

### Advantageous Effects of Invention

According to the technique of the present disclosure, it is possible to prevent deterioration in measurement accuracy occurring in an improvement in throughput and achieve both high throughput and highly accurate measurement.

### BRIEF DESCRIPTION OF DRAWINGS

FIG. 1 is a diagram illustrating an overall configuration example of a charged particle beam system 100 in which a charged particle beam apparatus is used as a scanning electron microscope according to a first embodiment.

FIG. 2 is a schematic diagram illustrating examples of trajectories (changes in the trajectories) of secondary electrons 12 at a high elevation angle and secondary electrons 13 at a low elevation angle when a primary electron radiation position is controlled using a primary electron deflector 22 at an upper stage and a primary electron deflector 23 at a lower stage and an example of correction of a change in the trajectory using a lower secondary electron deflector 31.

FIG. 3 is a diagram illustrating examples of an upper detector image 61 obtained with an upper detector 34 and a lower detector image 62 of a lower detector 35.

FIG. 4 is a schematic diagram illustrating examples of a black point silhouette 64-2 shown in the lower detector image 62 when the lower secondary electron deflector 31 performs an output (a voltage is applied and a current flows) and a black point silhouette 64-1 before the output, and an example of a black point silhouette position displacement vector 65.

FIG. 5 is a flowchart illustrating a control operation of the lower secondary electron deflector 31.

FIG. 6 is a flowchart illustrating a control operation of the lower secondary electron deflector 31 when a drift or vibration amount of the stage 42 is large.

FIG. 7 is a diagram illustrating an overall configuration example of a charged particle beam system 100 in which a charged particle beam apparatus is used as a scanning electron microscope according to a second embodiment.

FIG. 8 is a schematic diagram illustrating an example of a trajectory of secondary electrons 12 at a high elevation angle when a primary electron radiation position is controlled by a primary electron deflector 22 at an upper stage and a primary electron deflector 23 at a lower stage, and a lower secondary electron deflector 31 correcting the trajectory.

### DESCRIPTION OF EMBODIMENTS

According to an embodiment, a charged particle beam system (scanning electron microscope system) that acquires information regarding a sample by detecting a signal charged particle generated at a charged particle beam radiation position on a sample, and obtains a sample image by 2-dimensionally scanning an electron beam of a probe converged on the sample, detecting secondary electrons generated from the sample, and mapping a signal intensity of each scanning position will be disclosed. Hereinafter, embodiments of the present disclosure will be described.

### (1) First Embodiment

### Configuration Example of Charged Particle Beam System

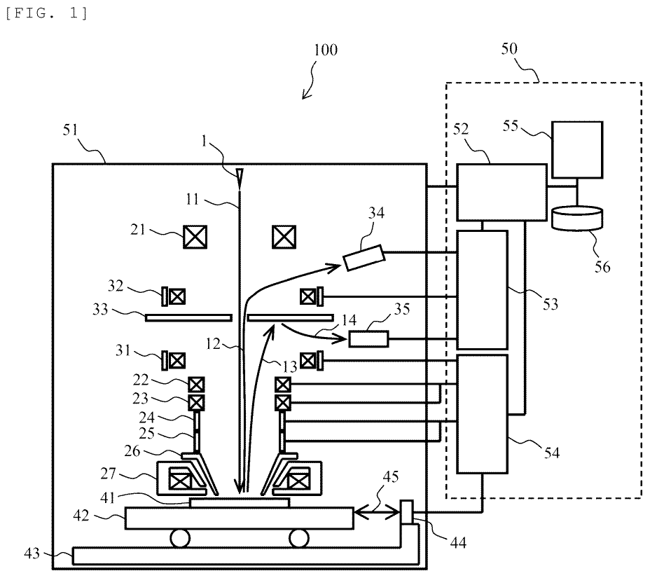

FIG. 1 is a diagram illustrating an overall configuration example of a charged particle beam system 100 in which a charged particle beam apparatus is used as a scanning electron microscope according to a first embodiment.

The charged particle beam system 100 includes a computer system 50 and a scanning electron microscope 51. The computer system 50 includes an overall control unit 52, a signal processing unit 53, a deflector control processing unit 54, an input/output unit 55, and a storage unit 56. The scanning electron microscope 51 includes an electron source 1, a condenser lens 21, a primary electron deflector 22 at an upper stage, a primary electron deflector 23 at a lower stage, a scanning deflector 24 at an upper stage, a scanning deflector 25 at a lower stage, an acceleration electrode 26 at a rear stage, an objective lens 27, a lower secondary electron deflector 31, an upper secondary electron deflector 32, a secondary electron diaphragm 33, an upper detector 34, a lower detector 35, a stage 42, a stage transport base 43, and a position detection unit 44.

In the scanning electron microscope 51, primary electrons 11 are generated from the electron source 1. The primary electrons 11 are converged by the condenser lens 21 to be deflected by the scanning deflector 24 at the upper stage and the scanning deflector 25 at the lower stage for 2-dimensional scanning on a sample 41. The deflected primary electrons 11 are accelerated by the acceleration electrode 26 at a rear stage, and then are converged on the sample 41 by the objective lens 27.

Secondary electrons are generated from radiation positions of the primary electrons 11 of the sample 41. The secondary electrons include surface information of the sample 41. Therefore, the surface information of the sample 41 can be obtained by radiating the primary electrons 11 to any position on the sample 41 and detecting information regarding the secondary electrons.

Of the generated secondary electrons, secondary electrons 12 at a high elevation angle close to 90 degrees come out through the secondary electron diaphragm 33 and then are deflected by the upper secondary electron deflector 32 to be converted into an electric signal by the upper detector 34. On the other hand, secondary electrons 13 at a low elevation angle less than the above elevation angle collide with the secondary electron diaphragm 33. Then, tertiary electrons 14 are generated from the secondary electron diaphragm 33 and are detected by the lower detector 35 to be converted into an electric signal.

The electric signals from the upper detector 34 and the lower detector 35 are transmitted to the signal processing unit 53. The signal processing unit 53 integrates signal intensities in synchronization with 2-dimensional scanning and generates an image obtained by mapping the signal intensities. The image is output to the input/output unit 55 via the overall control unit 52.

The sample 41 is placed on the stage 42 that can operate in 2-dimensional directions. This is because the primary electrons 11 are radiated to any coordinates on the sample 41. The position of the stage 42 is measured in real time with a position detection laser 45 by a laser interferometer of the position detection unit 44 installed on the stage transport base 43. A method of detecting a position by the position detection unit 44 is not limited to the above laser interferometer, and similar effects can be obtained with a linear scale. The radiation of the primary electrons 11 to any coordinates is realized by operating the stage 42.

Further, by causing the primary electron deflector 22 at the upper stage and the primary electron deflector 23 at the lower stage to deflect the primary electrons 11, it is possible to perform control such that the primary electrons 11 are radiated to a target position. The primary electron deflector 22 at the upper stage and the primary electron deflector 23 at the lower stage may be electrostatic deflectors or electromagnetic deflectors. The scanning deflector 24 at the upper stage and the primary electron deflector 22 at the upper stage, and the scanning deflector 25 at the lower stage and the primary electron deflector 23 at the lower stage can be controlled as one deflector.

In general, a stage operation allows for movement of a wide range, but alignment accuracy deteriorates. Conversely, primary electron deflection control offers a narrow movement range, but alignment accuracy is high. Therefore, in order to radiate the primary electrons 11 to target position coordinates on a sample designated by a user (hereinafter also referred to as an operator), control in which both the controls are combined is performed. At this time, in order to prevent the primary electron radiation position from being changed due to vibration or drift of the stage 42, stage position information obtained from the position detection unit 44 is input to the deflector control processing unit 54. The deflector control processing unit 54 calculates a primary electron deflection amount to ensure that the primary electron radiation position on the sample 41 is not changed and controls the primary electron deflector 22 at the upper stage and the primary electron deflector 23 at the lower stage. This control can be performed similarly in the scanning deflector 24 at the upper stage and the scanning deflector 25 at the lower stage.

### Reasons Why Detection Rate of Secondary Electrons Changes

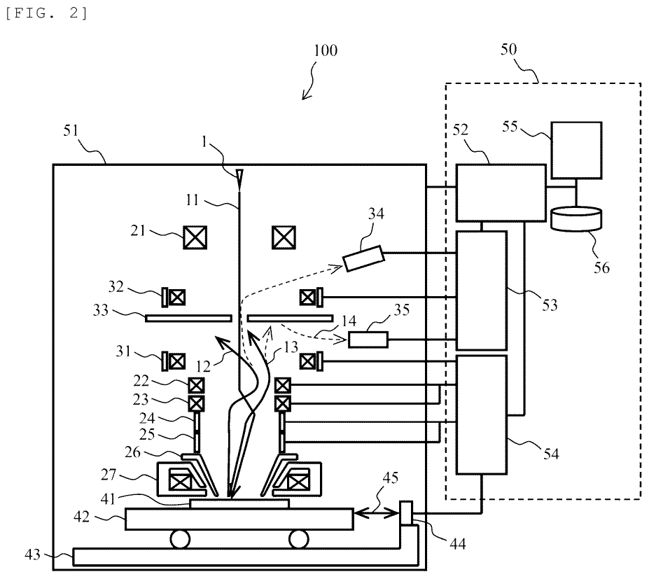

FIG. 2 is a schematic diagram illustrating examples of trajectories (changes in the trajectories) of the secondary electrons 12 at the high elevation angle and the secondary electrons 13 at the low elevation angle when a primary electron radiation position is controlled using the primary electron deflector 22 at the upper stage and the primary electron deflector 23 at the lower stage and an example of correction of the change in the trajectory using the lower secondary electron deflector 31.

As described in the above problem, the control of the deflection in the primary electron deflector has an influence on a trajectory of the secondary electrons. Therefore, a detection rate in the detector is changed. The secondary electrons generated at the primary electron radiation position can also be subjected to the deflection action of the primary electron deflector 22 at the upper stage and the primary electron deflector 23 at the lower stage. For example, when the secondary electrons 12 at the high elevation angle collide with the secondary electron diaphragm 33 and the secondary electrons 13 at the low elevation angle comes out of the secondary electron diaphragm 33 in the trajectory, the information regarding the secondary electrons detected by the upper detector 34 and the lower detector 35 may be changed.

In this regard, the trajectory (changed trajectory) can be corrected by the lower secondary electron deflector 31 provided between the primary electron deflector 22 at the upper stage and the secondary electron diaphragm 33. The lower secondary electron deflector 31 is a Wien filter and a deflector that can allow the primary electrons 11 to pass straight and deflect only the secondary electrons. Through the action of the lower secondary electron deflector 31, the trajectories of the secondary electrons 12 at the high elevation angle and the secondary electrons 13 at the low elevation angle can be deflected as indicated by a broken line. Accordingly, it is possible to prevent the detection rate of the secondary electrons detected by the upper detector 34 and the lower detector 35 from being changed.

### Output Adjustment Method of Lower Secondary Electron Deflector 31

Here, one form of an output adjustment method of the lower secondary electron deflector 31 with respect to a primary electron deflector output to prevent a change in a detection rate will be described.

### Example of Detection Image

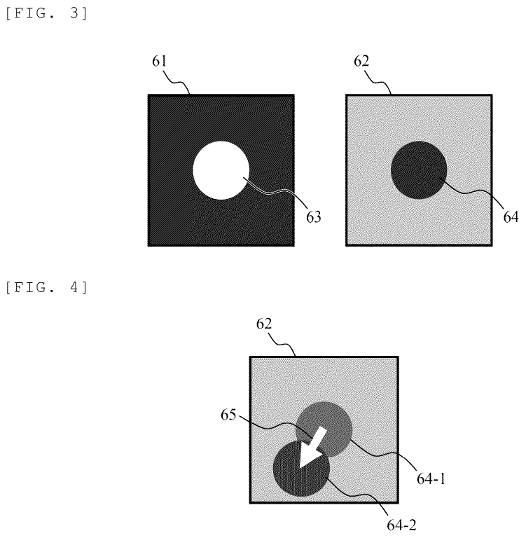

FIG. 3 is a diagram illustrating examples of an upper detector image 61 obtained with the upper detector 34 and a lower detector image 62 of the lower detector 35.

In 2-dimensional scanning of the primary electrons 11 by the scanning deflector 24 at the upper stage and the scanning deflector 25 at the lower stage, a detection rate is also changed in the detector by an output of the above deflector. In a center portion of an image, a white point silhouette 63 and a black point silhouette 64 in which the shape of the secondary electron diaphragm 33 is reflected are shown. Since the secondary electron diaphragm 33 is made typically to be axisymmetric with respect to an optical axis, a silhouette is indicated by a circular shape, but the shape of the secondary electron diaphragm 33 is not limited. Since a change in the detection rate during the 2-dimensional scanning is constant over time regardless of drift or the like of the stage, there is no influence on measurement accuracy.

During radiation position movement (during visual field movement) of the primary electrons 11, changes in the trajectories of the secondary electrons caused by outputs of the primary electron deflector 22 at the upper stage and the primary electron deflector 23 at the lower stage can be measured as displacement amounts of the positions of the white point silhouette 63 and the black point silhouette 64. Changes in the trajectories of the secondary electrons by the lower secondary electron deflector 31 can also be measured as displacement amounts of the positions of the white point silhouette 63 and the black point silhouette 64.

### Displacement Vector of Lower Detection Image

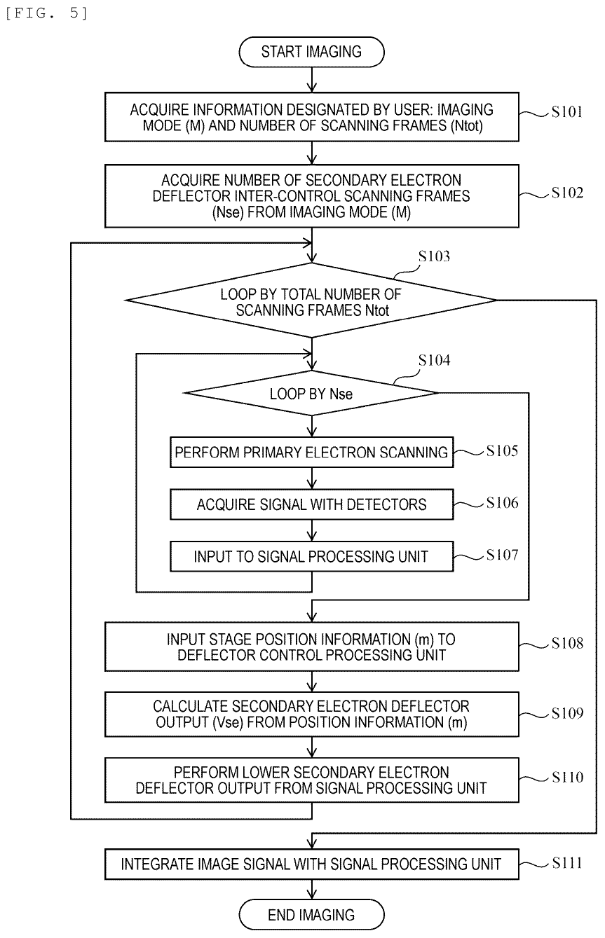

FIG. 4 is a schematic diagram illustrating examples of a black point silhouette 64-2 shown in the lower detector image 62 when the lower secondary electron deflector 31 performs an output (a voltage is applied and a current flows) and a black point silhouette 64-1 before the output, and an example of a black point silhouette position displacement vector 65.

The black point silhouette position displacement vector 65 indicates a positional displacement of the black point silhouette 64 before and after the output of the lower secondary electron deflector 31 and is a vector amount that depends on an output of the lower secondary electron deflector 31. During movement (during visual field movement) of the primary electron radiation position, movement of the black point silhouette 64 is also shown.

### Relational Expression between Movement Amount of Primary Electron Radiation Position and Output of Lower Secondary Electron Deflector 31

(i) In adjustment of the output of the lower secondary electron deflector 31, a relation between the output of the lower secondary electron deflector 31 and the black point silhouette position displacement vector 65 is acquired to obtain a coefficient A of Expression 1. As an examination result of the inventors, It is known that there is a linear relationship between the black point silhouette position displacement vector and the output of the lower secondary electron deflector 31 when a value of the black point silhouette position displacement vector corresponding to each output value is measured while changing the output of the lower secondary electron deflector 31. Therefore, the coefficient A can be obtained as an inclination of the linear relationship.

$$\begin{matrix}[ Expression 1 ] & \\ Black Point Silhouette Position Displacement Vector = Coefficient A \times Lower Secondary Electron Deflector Output & Expression 1\end{matrix}$$

(ii) A relation between the movement amount of the primary electron radiation position and the black point silhouette position displacement vector 65 is acquired to obtain a coefficient B of Expression 2. Similarly, as an examination result of the inventors, it is known that there is also a linear relationship between a change in the movement amount of the primary electron radiation position (a change amount of a first radiation position (visual field)=a change amount of position detection information) and a value of the black point silhouette position displacement vector corresponding to the visual field movement amount. Therefore, the coefficient B can also be obtained as an inclination of the linear relationship. The movement amount of the primary electron radiation position is a value for following drift or vibration of the stage 42.

$$\begin{matrix}[ Expression 2 ] & \\ Black Point Silhouette Position Displacement Vector = Coefficient B \times Movement Amount of Primary Electron Radiation Position & Expression 2\end{matrix}$$

(iii) From Expressions 1 and 2, a relational expression of the movement amount of the primary electron radiation position and the output of the lower secondary electron deflector 31 can be obtained as in Expressions 3 and 4.

$$\begin{matrix}[ Expression 3 ] & \\ Lower Secondary Electron Deflector Output = Coefficient C \times Movement Amount of Primary Electron Radiation Position & Expression 3\end{matrix}$$

$$\begin{matrix}[ Expression 4 ] & \\ Coefficient C = Coefficient A \hat{} ( - 1 ) \times Coefficient B & Expression 4\end{matrix}$$

The output of the lower secondary electron deflector 31, the movement amount of the primary electron radiation position, and the black point silhouette position displacement vector are vector amounts of two components. The coefficients A, B, and C may be either scalar amounts or 2-dimensional matrixes. The coefficients A, B, and C can be obtained as adjustment parameters experimentally or by a simulation in advance for each apparatus (for example, for each apparatus before shipment) and stored in the storage unit 56 to be read for use. The coefficients A, B, and C can be obtained again for each measurement. The control expressions in Expressions 1, 2, 3, and 4 are simple examples and can also be set as polynomials including quadratic or more components of each expression for high accuracy of control. The expressions may be control expressions in which the coefficients A, B, and C are changed depending on an output range of the lower secondary electron deflector 31 and a range of the movement amount of the primary electron radiation position.

(iv) When primary electron deflection control is performed in accordance with vibration or drift of the position of a stage (for making the primary electron radiation position on the sample constant), a primary electron deflector output is changed at a certain cycle (for example, at timing of vibration) based on information from the position detection unit 44. Therefore, in secondary electron trajectory control, it is also necessary to change an output in conjunction with the primary electron deflector output. At this time, the coefficient C is input in advance from the storage unit 56 to the deflector control processing unit 54. Then, a lower secondary electron deflector output is calculated using the information from the position detection unit 44. From this calculation value, the output of the lower secondary electron deflector 31 is output in conjunction with the primary electron deflector output.

(v) Control of Primary Electron Deflector Using Position Shift Information of Image (hereinafter referred to as “position movement amount information” or “visual field movement amount”) Without Using Information from Position Detection Unit 44.

The primary electron deflector 22 at the upper stage and the primary electron deflector 23 at the lower stage can also be controlled based on position shift information of an image. A shift amount from a target position of the image integrated by the signal processing unit 53 is calculated by the overall control unit 52 and is input to the deflector control processing unit 54. Outputs of the primary electron deflector 22 at the upper stage and the primary electron deflector 23 at the lower stage for supplementing a shift amount are calculated based on this information. As the shift amount, a relative shift amount from a position at the time of arrival of the target position and start of imaging can be used or a shift amount from a model image at the target position stored in the storage unit 56 can also be used. A calculation expression at this time can also be calculated by a simulation or a calculation expression stored in advance as an adjustment parameter in the storage unit 56 can also be read.

(vi) Use of Wien Filter type Deflector When the upper secondary electron deflector 32 and the lower secondary electron deflector 31 are configured as Wien filter type deflectors, it is ideal that secondary electron deflection can be deflected without an influence on the primary electrons 11. However, actually, the influence on the primary electrons 11 cannot be completely eliminated due to an influence of machining tolerance, assembly tolerance, or the like. Therefore, measurement accuracy of an image is likely to deteriorate due to a slight change in the radiation position of the primary electrons 11 when an output of the upper secondary electron deflector 32 and/or the lower secondary electron deflector 31 is changed during 2-dimensional scanning. In this case, by operating the deflector in an operation flow to be described below, it is possible to perform control by preventing an influence of the secondary electron deflector on the primary electrons 11.

### Control Operation of Lower Secondary Electron Deflector 31 When Drift or Vibration Amount of Stage 42 is Small

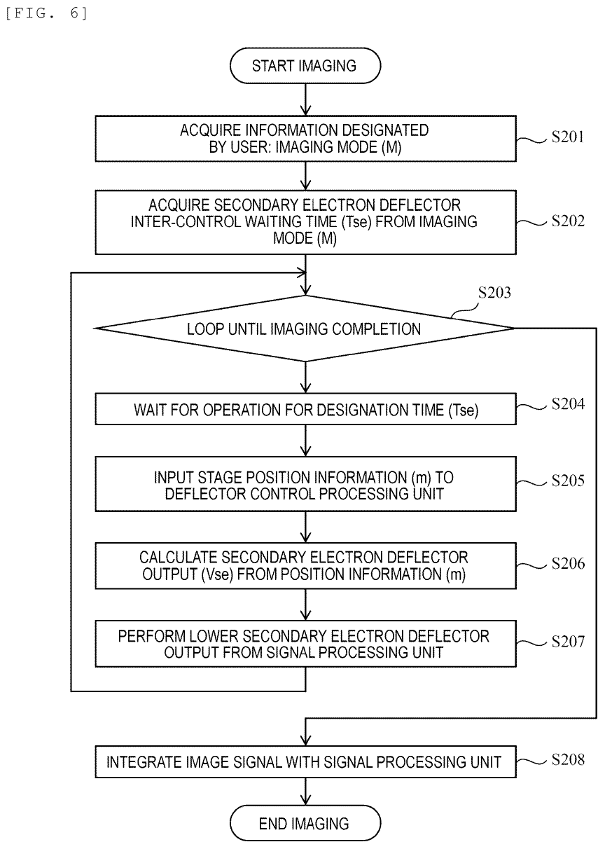

FIG. 5 is a flowchart illustrating a control operation of the lower secondary electron deflector 31. In the control operation, the lower secondary electron deflector 31 is controlled between scanning frames (a time between frames). Here, scanning frames are units of images obtained single 2-dimensional scanning. “A case in which a drift or vibration amount of the stage 42 is small” is, for example, a case in which a drift amount or vibration amount is less than a predetermined threshold.

### (i) Step 101

The overall control unit 52 acquires information regarding an imaging mode (M) and the number of scanning frames (Ntot: the number of acquired (integrated) frames) input (designated) from the input/output unit 55 by the user. Here, the imaging mode is, for example, a time (imaging speed) taken to capture a one-frame image. The number of scanning frames (Ntot) is a desired number of frames integrated finally. For example, the user can designate Ntot=256.

### (ii) Step 102

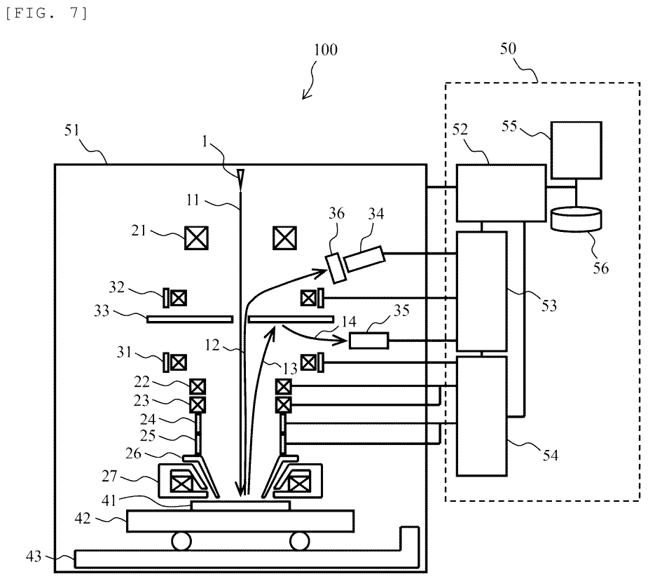

The overall control unit 52 reads the number of secondary electron deflector inter-control scanning frames (Nse) stored in association with the designated imaging mode from the storage unit 56. Here, the number of secondary electron deflector inter-control scanning frames (Nse) is a value indicating at which frame a secondary electron deflection output (here, a lower secondary electron deflection output) is given in the number of scanning frames (Ntot). For example, when the number of secondary electron deflector inter-control scanning frames corresponding to a designated imaging mode is Nse=4, a secondary electron deflection output is given whenever four frames are acquired. In the case of Nse=1, a secondary electron deflection output is given whenever one frame is acquired. That is, the secondary electron deflection output control is performed at a predetermined period interval although the length of the interval varies depending on an imaging mode. The same applies for secondary electron deflection output control in FIG. 6 to be described below. That is, in the case of FIG. 6, the secondary electron deflection output control is performed at each predetermined waiting time (designated time) regardless of a scanning period of the primary electrons (a time necessary to scan one frame with the primary electrons).

### (iii) Step 103

The overall control unit 52 controls the deflector control processing unit 54, the upper detector 34, the lower detector 35, and the signal processing unit 53 to repeat the processes from steps 104 to 110 until the number of acquired frames becomes the number of scanning frames (Ntot).

### (iv) Step 104

The overall control unit 52 controls the deflector control processing unit 54, the upper detector 34, the lower detector 35, and the signal processing unit 53 to perform the processes from steps 105 to 107 by Nse times. That is, whenever the scanning frames corresponding to the number Nse are acquired, the processes of giving the lower secondary electron deflection output (steps 108 to 110) are performed.

### (v) Step 105

The deflector control processing unit 54 scans the sample 41 with the primary electrons and generates the secondary electrons.

### (vi) Steps 106 and 107

The upper detector 34 and the lower detector 35 acquire a signal (corresponding to one frame) of the generated secondary electrons and inputs the signal to the signal processing unit 53.

When the processes from steps 105 to 107 are repeated by Nse times and the images corresponding to the Nse frames are acquired, the process proceeds to step 108.

### (vii) Step 108

The overall control unit 52 inputs stage position information acquired from the position detection unit 44 to the deflector control processing unit 54. The stage position information corresponds to the above-described movement amount of the primary electron radiation position and is information indicating a position shift amount from a first radiation position or a previous radiation position.

### (viii) Step 109

The overall control unit 52 calculates a lower secondary electron deflector output using the stage position information as the movement amount of the primary electron radiation position based on the above Expression 3, and delivers information regarding the calculated lower secondary electron deflector output to the signal processing unit 53.

### (ix) Step 110

The signal processing unit 53 outputs a value of the lower secondary electron deflector output to the deflector control processing unit 54. The deflector control processing unit 54 operates the lower secondary electron deflector 31 (applies a voltage and flows a current) based on the value of the lower secondary electron deflector output.

When the above processes are repeated until a total number of scanning frames is Ntot times, the process proceeds to step 111.

### (x) Step 111

The signal processing unit 53 integrates image signals of the frames corresponding to the number of scanning frames Ntot and delivers an integrated value to the overall control unit 52. The overall control unit 52 outputs the integrated value of the image signals from the input/output unit 55 (displays the integrated value on a screen).

The number of secondary electron deflector inter-control scanning frames (Nse) is selected based on a required time per scanning frame (imaging mode) and magnitude of drift or vibration of the stage 42. As a time interval of the secondary electron deflector output becomes shorter, a change in a detection rate in the detector can be reduced. However, since a longer time interval can reduce an influence of the secondary electron deflector output on an image, determination is made in consideration of such trade-off. When drift or vibration of the stage 42 is large, a change in the detection rate is large with an increase in the movement amount of the primary electron radiation position. Therefore, it is necessary to shorten the time interval. For each imaging mode, a required time per scanning frame can be determined, and thus magnitude of the drift or the vibration of the stage 42 is determined according to an apparatus configuration. Accordingly, the number of secondary electron deflector inter-control scanning frames Nse can be appropriately set for each imaging mode. Of course, as a parameter designated by the user, the number of secondary electron deflector inter-control scanning frames Nse may be input. Under all the conditions regardless of the parameter set for each imaging mode, an operation can also be performed with the same number of secondary electron deflector inter-control scanning frames Nse.

In the present embodiment, a control flow in the secondary electron deflector has been described. Here, visual field shift correction control in the primary electron deflector in association with a stage position shift is performed independently. However, when measurement accuracy deteriorates due to a change in the output of the primary electron deflector in the scanning frames due to a problem of responsiveness of the primary electron deflector, the visual field movement between the scanning frames can be corrected by calculating the output of step 109 of the flow and setting the primary electron deflector as an output destination of step 110, and thus it possible to curb deterioration in measurement accuracy.

On the other hand, when the drift or vibration of the stage 42 is large and the change in the detection rate cannot be corrected even in a single operation of the scanning frames, it is necessary to shorten the time interval of the secondary electron deflector output and change the secondary electron deflector output even during 2-dimensional scanning. At that time, control can be performed with the operation flowchart of FIG. 6.

### Control Operation of Lower Secondary Electron Deflector 31 When Drift or Vibration Amount of Stage 42 is Large

,FIG. 6 is a flowchart illustrating a control operation of the lower secondary electron deflector 31 when a drift or vibration amount of the stage 42 is large. Here, “the case in which the drift or vibration amount of the stage 42 is large” is, for example, a case in which the drift amount or vibration amount is equal to or greater than the predetermined threshold. The overall control unit 52 can determine whether to perform the control operation of FIG. 5 or 6 by comparing a separately measured drift amount or vibration amount or a preset drift amount or vibration amount unique to the stage (for example, stored as a set value in the storage unit 56) with the threshold. Alternatively, the overall control unit 52 may determine whether to perform the process of FIG. 5 or the process of FIG. 6 in association with the imaging mode (since the drift amount is small when an imaging speed is fast). When the overall control unit 52 determines that the drift amount or vibration amount of the stage 42 cannot be corrected after execution of the control operation of FIG. 5, the control operation of FIG. 6 may be performed.

### (i) Step 201

The overall control unit 52 acquires information regarding the imaging mode (M) input (designated) by the user from the input/output unit 55. Here, as described above, the imaging mode is, for example, a time (imaging speed) taken to capture a one-frame image.

### (ii) Step 202

The overall control unit 52 reads secondary electron deflector control waiting time (Tse) stored in association with the designated imaging mode from the storage unit 56. The secondary electron deflector control waiting time (Tse) can be determined for each imaging mode or may be set with the same value for all the conditions.

### (iii) Step 203

The overall control unit 52 controls the deflector control processing unit 54, the upper detector 34, the lower detector 35, and the signal processing unit 53 to repeat the processes from steps 204 to 207 until imaging completion. Although not illustrated in FIG. 6, it is assumed that the scanning on the sample with the primary electrons and the process of acquiring the secondary electrons (the process of acquiring a frame image) by the detector are performed independently of the control operation of the lower secondary electron deflector 31.

### (vi) Step 204

The overall control unit 52 waits by the designated time (the secondary electron deflector control waiting time Tse) without performing the imaging operation after an instruction to start imaging is input. Accordingly, it is possible to stabilize the output of the image and acquire an image with sufficient image quality. Since the designated time =the frame scanning time is not established, the secondary electron deflection output control may be performed even during a scanning operation.

### (v) Step 205

The overall control unit 52 inputs the stage position information acquired from the position detection unit 44 to the deflector control processing unit 54.

### (vi) Step 206

The overall control unit 52 calculates the lower secondary electron deflector output using the stage position information as the movement amount of the primary electron radiation position based on the above Expression 3, and delivers information regarding the calculated lower secondary electron deflector output to the signal processing unit 53.

### (vii) Step 207

The signal processing unit 53 outputs a value of the lower secondary electron deflector output to the deflector control processing unit 54. The deflector control processing unit 54 operates the lower secondary electron deflector 31 (applies a voltage and flows a current) based on the value of the lower secondary electron deflector output.

The processes from steps 204 to 207 are repeated until imaging completion. When the imaging is completed, the process proceeds to step 208.

### (viii) Step 208

The signal processing unit 53 integrates the captured image signals and delivers an integrated value to the overall control unit 52. The overall control unit 52 outputs an integrated value of the mage signals from the input/output unit 55 (displays the integrated value on a screen).

### (2) Second Embodiment

### Configuration Example of Charged Particle Beam System

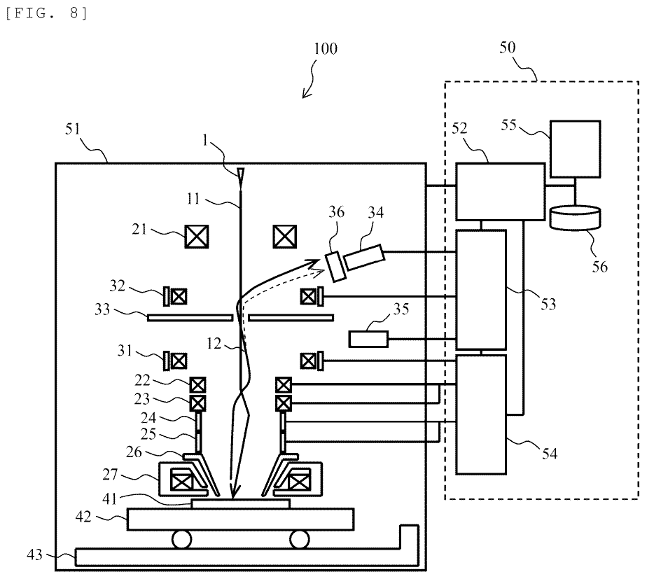

FIG. 7 is a diagram illustrating an overall configuration example of a charged particle beam system 100 in which a charged particle beam apparatus is used as a scanning electron microscope according to a second embodiment.

The charged particle beam system 100 in FIG. 7 includes a computer system 50 and a scanning electron microscope 51 as in the charged particle beam system 100 according to the first embodiment. The computer system 50 has a similar configuration as the case of the first embodiment. When the scanning electron microscope 51 according to the second embodiment is compared with the scanning electron microscope according to the first embodiment, the position detection unit 44 is not included and an energy filter 36 is added.

Since the charged particle beam apparatus (the scanning electron microscope 51) according to the second embodiment does not include the above-described position detection unit, an output of the lower secondary electron deflector 31 is set based not on the stage position information but on image information. Hereinafter, output calculation of the lower secondary electron deflector 31 based on the image information will be described.

### Output Calculation of Lower Secondary Electron Deflector Based on Image Information

The black point silhouette 64 of the lower detector image 62 illustrated in FIG. 4 moves depending on the primary electron deflector output. Therefore, the black point silhouette position displacement vector 65 is calculated from the lower detector image 62 in a previous scanning frame through image processing. The overall control unit 52 calculates an output of the lower secondary electron deflector 31 based on Expression 1 and information regarding the calculated black point silhouette position displacement vector 65.

In imaging, the overall control unit 52 acquires silhouette position information from the images integrated by the signal processing unit 53, calculates the black point silhouette position displacement vector 65, and inputs the black point silhouette position displacement vector 65 to the deflector control processing unit 54. The deflector control processing unit 54 calculates the lower secondary electron deflector output corresponding to the black point silhouette position displacement vector 65 based on information regarding the coefficient A and Expression 1 read from the storage unit 56, and outputs the lower secondary electron deflector 31 (applies a voltage and flows a current).

Here, the method of using the positional information of the black point silhouette 64 seen in the lower detector image 62 has been described, but control can also be performed by the same method with the positional information of the white point silhouette 63 seen in the upper detector image 61.

### Control of Angle of Incidence of Secondary Electrons at High Elevation Angle

The method of curbing the change in the detection rate of the plurality of detectors (the upper detector 34 and the lower detector 35) has been described, but control can also be performed such that an angle of incidence of the secondary electrons 12 at the high elevation angle incident on the upper detector 34 and the energy filter 36 is constant.

As illustrated in FIG. 7, when the energy filter 36 is provided between the upper detector 34 and the upper secondary electron deflector 32, energy of the secondary electrons 12 at the high elevation angle can be determined and detected. At that time, however, when the angle of incidence of the secondary electrons 12 at the high elevation angle incident on the energy filter 36 is changed, a threshold of the secondary electrons at the high elevation angle to be filtered out by the energy filter 36 may be changed, filter accuracy may deteriorate, and thus measurement accuracy may deteriorate.

Therefore, the change in the angle of incidence of the secondary electrons 12 at the high elevation angle on the energy filter 36 is curbed by controlling an output of the lower secondary electron deflector 31 in accordance with the movement amount of the primary electron radiation position.

FIG. 8 is a schematic diagram illustrating an example of a trajectory of the secondary electrons 12 at the high elevation angle when a primary electron radiation position is controlled by the primary electron deflector 22 at the upper stage and the primary electron deflector 23 at the lower stage, and the lower secondary electron deflector 31 correcting the trajectory. In FIG. 8, a trajectory before deflection by the lower secondary electron deflector 31 is indicated with a solid line and a trajectory after the deflection is indicated with a broken line. In the trajectory indicated by the solid line, the secondary electrons at the high elevation angle is not vertically incident on the energy filter 36. Therefore, accuracy at the energy filter 36 deteriorates. On the other hand, in the trajectory after the deflection indicated by the broken line, the secondary electrons at the high elevation angle are vertically incident on the energy filter 36. Therefore, it can be seen that the measurement accuracy can be maintained despite the change in the primary electron radiation position.

An example of adjustment of the control will be described. The overall control unit 52 acquires a detection signal before movement of the primary electron radiation position with the energy filter 36 operated from the signal processing unit 53, and then moves the primary electron radiation position (visual field). Similarly, the overall control unit 52 acquires the detection signal at the time of movement of the primary electron radiation position from the signal processing unit 53. Then, the overall control unit 52 compares images before and after the movement of the primary electron radiation position (visual field). Thereafter, the overall control unit 52 repeats similar detection while causing the lower secondary electron deflector 31 to perform output and obtains the lower secondary electron deflector output that most matches the image before the movement of the radiation position. Accordingly, a relational expression of the optimum lower secondary electron deflector output with respect to the primary electron radiation position is obtained for control. Apart from this method, an output expression can also be obtained by calculating an optimum output value by a simulation. Since the present control process is similar to the process described in FIGS. 5 and 6, detailed description thereof will be omitted.

### (3) Conclusion

(i) In the first and second embodiments, the improvement in the detection rate of the detectors (the upper detector 34 and the lower detector 35) and the curbing of the change in the angle of incidence of the secondary electrons 12 at the high elevation angle on the energy filter have been described by controlling the lower secondary electron deflector 31, but it is needless to say the similar control can be performed with the upper secondary electron deflector 32.

(ii) In one form of the present disclosure, in the charged particle beam system 100 including the computer system 50 and the scanning electron microscope (charged particle beam apparatus) 51, the computer system 50 performs output control of the second deflector (the lower secondary electron deflector 31 and/or the upper secondary electron deflector) based on the positional information (visual field movement amount) detected by the position detection device (the position detection unit 44). Here, the output of the second deflector can be calculated by multiplying the movement amount of the primary electron radiation position based on the positional information (the position shift amount of the stage) by the predetermined parameter (see the above Expressions 3 and 4). Since the deflection output control of the secondary electrons is performed along with the deflection control of the primary electrons based on the positional information in this way, the measurement accuracy can also be improved while improving a throughput. (achieve both the improvement in the throughput and the improvement in measurement accuracy)

The deflection output control of the secondary electrons can be selectively performed during a period (scanning period interval) between a 2-dimensional scanning period and a subsequent 2-dimensional scanning period by a charged particle beam (primary electrons). That is, each time single 2-dimensional scanning on a measurement target sample ends, an image is acquired while determining whether r to perform the deflection output control of the secondary electrons. For example, the deflection output control of the secondary electrons may be performed whenever one-frame image may be acquired or the deflection output control of the secondary electrons may be performed whenever a plurality of frame images are acquired. Here, when a drift amount or vibration amount of the stage is greater than the predetermined threshold (when the scanning speed is slower than a predetermined speed), the deflection output control of the secondary electrons may be performed at each predetermined time interval (designated time) (even during scanning) irrespective of the scanning period interval. In this way, the deflection output control of the secondary electrons can be performed at an appropriate frequency in accordance with an imaging mode (low or high scanning speed), it is possible to improve the measurement accuracy without deteriorating the throughput.

(iii) In another form of the present disclosure, in the charged particle beam system 100, the computer system 50 calculates the positional information (the visual field movement amount) from the images with the signals detected by the detectors, and selectively performs the output control of at least one of a first deflector (the primary electron deflector 22 at the upper stage and/or the primary electron deflector 23 at the lower stage) and a second deflector (the lower secondary electron deflector 31 and/or the upper secondary electron deflector) after end of the single 2-dimensional scanning period by a charged particle beam based on a position shift amount indicated by the positional information. Here, “selectively” is synonymous with the above-described term. Even when the position detection unit 44 is not used in this way, the position shift amount from the shift amount of the acquired image can be detected. Therefore, it is possible to decrease the number of apparatus components and reduce an apparatus manufacturing As described above, since the deflection control of the primary electrons and the deflection control of the secondary electrons can be performed based on the positional information (visual field movement amount), it is possible to improve the measurement accuracy while improving the throughput (achieve both the improvement in the throughput and the improvement in measurement accuracy).

(iv) A function of the present embodiment can also be implemented by a program code of software. In this case, a storage medium recording the program code is provided to a system or an apparatus. A computer (or a CPU or an MPU) of the system or the apparatus reads the program code stored in the storage medium. In this case, the program code itself read from the storage medium implements the function of the above-described embodiment, and the program code itself and the storage medium storing the program code are constituents of the present disclosure. Examples of the storage medium that provides the program code include a flexible disk, a CD-ROM, a DVD-ROM, a hard disk, an optical disc, a magneto-optical disc, a CD-R, a magnetic tape, a nonvolatile memory card, and a ROM.

Based on an instruction of the program code, an operating system (OS) or the like operating on a computer may perform some or all of the actual processes so that a function of the above-described embodiment is implemented through the process. Further, after the program code read from the storage medium is written on a memory of the computer, a CPU or the like of the computer may perform some or all of the actual processes in response to an instruction of the program code so the function of the above-described embodiment is implemented through the process.

Further, the program code of the software implementing the function of the embodiment may be transmitted via a network, the program code may be stored in a storage unit such as a memory or a hard disk of the system or the apparatus, or a storage medium such as a CD-RW or a CD-R, so that the computer (or the CPU or the MPU) of the system or the apparatus can read and execute the program code stored in the storage unit or the storage medium at the time of use.

The processes and techniques described here are not inherently involved in any specific apparatus and can be implemented through an appropriate combination of constituent elements. Furthermore, a dedicated apparatus may be constructed to performs the steps of the methods described here. Additionally, by appropriately combining the various constituent elements disclosed in the present embodiment, various technical elements can be formed. For example, certain constituent elements described in the embodiment may be omitted. The present disclosure has been described with regard to specific examples, but these are provided to facilitate understanding and not to limit the scope. It will be readily apparent to those skilled in the art that there are numerous combinations of hardware, software, and firmware appropriate for implementing the techniques of the present disclosure. For instance, the described software can implement the technique of the present disclosure using a wide range of programming or scripting languages such as assembler, C/C++, Perl, Shell, PHP, and Java (registered trademark).

In the above-described embodiment, the control lines or information lines indicate lines considered to be necessary for description and are not all the control lines and information lines necessary for implementation. Actually, substantially all the configurations may be connected to each other.

Additionally, those skilled in the art will clearly understand other implementations of the present disclosure from the consideration of the specifications and embodiments of the present disclosure disclosed herein. The descriptions and specific examples in the specification are merely illustrative, and the scope and spirit of the present disclosure are defined by the following claims.

### REFERENCE SIGNS LIST

1: electron source
11: primary electrons
12: secondary electrons at high elevation angle
13: secondary electrons at low elevation angle
14: tertiary electrons
21: condenser lens
22: primary electron deflector at upper stage
23: primary electron deflector at lower stage
24: scanning deflector at upper stage
25: scanning deflector at lower stage
26: acceleration electrode at rear stage
27: objective lens
31: lower secondary electron deflector
32: upper secondary electron deflector
33: secondary electron diaphragm
34: upper detector
35: lower detector
36: energy filter
41: sample
42: stage
43: stage transport base
44: position detection unit
45: position detection laser
51: scanning electron microscope
52: overall control unit
53: signal processing unit
54: deflector control processing unit
55: input/output unit
56: storage unit
61: upper detector image
62: lower detector image
63: white point silhouette
64: black point silhouette
65: black point silhouette position displacement vector

1. A charged particle beam system comprising:
a charged particle beam apparatus including
a charged particle source configured to emit a charged particle beam,
a stage on which a sample is placed,
a first deflector configured to deflect the charged particle beam,
a second deflector configured to deflect a signal particle emitted from the sample,
a detector configured to detect the signal particle, and
a position detection device configured to detect a position of the sample or the stage; and
a computer system configured to control an operation of the charged particle beam apparatus,
wherein the computer system performs output control of the second deflector based on positional information detected by the position detection device.

2. The charged particle beam system according to claim 1, wherein the computer system calculates an output of the second deflector by multiplying a visual field movement amount by the first deflector by a predetermined parameter.

3. The charged particle beam system according to claim 1, wherein the computer system selectively performs the output control of the second deflector after one 2-dimensional scanning period by the charged particle beam ends.

4. The charged particle beam system according to claim 1, wherein the computer system performs the output control of the second deflector at each predetermined time interval.

5. The charged particle beam system according to claim 4, wherein the computer system performs the output control of the second deflector at each 2-dimensional scanning period interval associated with an input imaging mode and corresponding to a predetermined number of frames by the charged particle beam.

6. The charged particle beam system according to claim 5, wherein the computer system performs the output control of the second deflector between a scanning process corresponding to a first predetermined number of frames and a scanning process corresponding to a second predetermined number of frames and continuing from the scanning process corresponding to the first predetermined number of frames.

7. The charged particle beam system according to claim 4, wherein the computer system performs the output control of the second deflector at each designated time associated with the input imaging mode when the sample is scanned with the charged particle beam and imaged.

8. The charged particle beam system according to claim 1, wherein the position detection device is a laser interferometer including a radiation source that radiates a laser to the sample or the stage and a reflected light detector that detects reflected light of the laser.

9. A charged particle beam system comprising:
a charged particle beam apparatus including
a charged particle source configured to emit a charged particle beam,
a stage on which a sample is placed,
a first deflector configured to deflect the charged particle beam;
a second deflector configured to deflect a signal particle emitted from the sample, and
a detector configured to detect the signal particle; and
a computer system configured to control an operation of the charged particle beam apparatus,
wherein the computer system calculates positional information of the sample or the stage from an image by a signal detected by the detector, and selectively performs output control of at least one of the first deflector and the second deflector based on the positional information of the sample or the stage after one 2-dimensional scanning period by the charged particle beam ends.

10. The charged particle beam system according to claim 9, wherein the computer system performs the output control of at least one of the first deflector and the second deflector based on the positional information before a subsequent 2-dimensional scanning period starts after the one 2-dimensional scanning period ends.

11. A charged particle beam system comprising:
a charged particle beam apparatus including
a charged particle source configured to emit a charged particle beam,
a stage on which a sample is placed,
a first deflector configured to deflect the charged particle beam,
a second deflector configured to deflect a signal particle emitted from the sample,
a detector configured to detect the signal particle, and
a position detection device configured to detect a position of the sample or the stage; and
a computer system configured to control an operation of the charged particle beam apparatus,
wherein the computer system selectively performs output control of at least one of the first deflector and the second deflector based on positional information detected by the position detection device after one 2-dimensional scanning period by the charged particle beam ends.

12. The charged particle beam system according to claim 11, wherein the computer system performs the output control of at least one of the first deflector and the second deflector based on the positional information before a subsequent 2-dimensional scanning period starts after the one 2-dimensional scanning period ends.

13. The charged particle beam system according to claim 11, wherein the position detection device is a laser interferometer including a radiation source that radiates a laser to the sample or the stage and a reflected light detector that detects reflected light of the laser.
